(19) United States
(12) Patent Application Publication
(10) Pub. No.: US 2025/0261560 A1
(43) Pub. Date: Aug. 14, 2025

(54) THERMOELECTRIC DEVICE WHERE A JUNCTION ALTERNATES BETWEEN HOT AND COLD BY STORING CHARGE

(71) Applicant: Tarek Makansi, Tucson, AZ (US)

(72) Inventor: Tarek Makansi, Tucson, AZ (US)

(21) Appl. No.: 18/857,171

(22) PCT Filed: Jun. 20, 2023
(86) PCT No.: PCT/US2023/025750

§ 371 Date: Oct. 15, 2024

Related U.S. Application Data
(60) Provisional application No. 63/390,851, filed on Jul. 20, 2022.
(60) Provisional application No. 63/421,180, filed on Nov. 1, 2022.

(51) Int. Cl. H10N 10/17; F25B 21/00; H10N 10/856; H10N 19/00

(52) U.S. Cl. CPC H10N 10/17; H10N 10/856; H10N 19/00; F25B 21/00

(57) ABSTRACT

A novel thermoelectric device with charge flowing across one junction stores electrical charge instead of flowing the charge across another thermoelectric junction, thereby preventing proximal hot and cold sides that lead to thermal backflow in the prior art. This novel device also allows for minimization of the thickness of the thermoelectric layer, reducing electrical resistance that limits efficiency in prior art devices. Practical heating and cooling systems are shown based on the novel thermoelectric device.

### BACKGROUND

Solid-state devices that heat, cool, and reversibly convert heat to electricity are known as thermoelectric devices. Unfortunately, traditional thermoelectric devices are very inefficient compared to rotating machinery like compressors for cooling and heating or gas and steam turbines for converting heat to electricity. The root cause of inefficiency of thermoelectric devices is embedded in the tradeoff between the thermal separation of hot and cold junctions (less separation causes heat backflow) and their electrical separation (more separation increases resistive losses). When fully optimized, this tradeoff still results in an inefficient device, even after six decades of material research and other efforts.

If an efficient thermoelectric device existed, it could replace the rotating machinery used extensively today, and have the potential to greatly reduce environmental noise, eliminate ozone-layer destruction from refrigerant fluids, eliminate distribution losses of ducting and transmission lines, and greatly reduce the use of fossil fuels that lead to climate change and global warming.

Hence, the need exists for a more efficient thermoelectric device.

### SUMMARY

A prior art thermoelectric device has two junctions at each end of a thermoelectric material (“thermoelectric”). A thermoelectric material may be either p-type or n-type, and the type determines whether heat flows in the same direction as the electrical current or in the opposite direction. In the remainder of this summary and description, an n-type thermoelectric material will be assumed. Without limitation, this invention also encompasses the substitution of p-type material with obvious changes in device polarity.

In a prior art thermoelectric device, as electrical current flows across a metal-to-(n-type) thermoelectric junction, that junction heats. Then, a few millimeters away, the same electrical current flows out through a thermoelectric-to-metal junction, and that junction cools (the Peltier effect). The connection of the hot and cold junctions by a few millimeters of solid thermoelectric material enables heat to backflow to the cold side, destroying the cooling efficiency.

This invention adds storage of electric charge to the thermoelectric material adjacent to a dielectric layer. As a result, an electric current flow across a thermoelectric (n-type)-to-metal junction will only cool as the charge is removed from inside the thermoelectric. The current does not simultaneously flow out through an opposite junction and thereby does not generate unwanted heat nearby, as in the prior art.

Prior art has considered the native thermoelectric behavior of devices that store charge such as capacitors and batteries, and this prior art is summarized in [3,4,5] and other publications. However, note that these prior art devices, while exhibiting both charge storage and thermoelectric behavior, they require a temperature delta between two thermoelectric junctions within one battery or within one capacitor, and therefore suffer the same heat backflow through the device as other prior art thermoelectric devices.

This invention teaches a charge storage device with one thermoelectric junction wherein the entire device maintains one temperature that may change over time. The invention device does not rely on a temperature gradient within the device as in the prior art.

This cooling-only behavior of the invention continues as long as electrical charge can be removed from the thermoelectric material. Once its charge capacity is depleted, the thermoelectric will need to be re-charged by allowing current to flow in reverse across a thermoelectric-to-metal junction, during which time the heat is re-created.

The addition of charge storage to the thermoelectric material enables the junction to cool for a period of time (while discharging) and then to heat for a period of time (while charging), satisfying the conservation laws of thermodynamics. If the junction is physically located inside an insulated enclosure (refrigerator, building, or wearable) while cooling and then moved outside while heating, then the invention can be used to build a refrigerator, freezer, air conditioner, or body-cooling garment.

The alternating movement of the invention's thermoelectric junction from a cold enclosure while cooling to a hot enclosure while heating eliminates the thermal backflow through the thermoelectric material of the prior art. The prior art requires simultaneous heating and cooling at either end of a thermoelectric material. Furthermore, a very thin thermoelectric layer can be used in the junction of the invention, greatly reducing the electrical resistance losses of the prior art.

Hence, this invention addresses the two primary destroyers of efficiency of prior-art thermoelectric devices: heat back flow and electrical resistance, in a novel manner.

A new loss mechanism is introduced by this invention, however, and that is the overcoming of the thermal mass of the device as it transitions from heating to cooling and back again. Essentially, the device must make itself cold before it can start cooling its surroundings. It will be shown that this loss mechanism can be managed by design, with modern but available charge storage capabilities, to still allow the invention device to achieve very high efficiency.

In this invention, heating is conversely achieved easily by having the junction inside the enclosure while heating and outside while cooling. So, the invention can be used to build an efficient heater, oven, stove, or body-heating garment as well. Having both heating and cooling capabilities, the invention acts as a heat pump and can move heat in either direction as desired. A working fluid like air or water can also be added to re-direct the heat or cool from the junction to the desired location (inside or outside the enclosure) at each phase, rather than physically moving the junctions.

This invention can also convert heat to electricity by having two junctions that each store charge, electrically connected, but located in separate enclosures maintained at different temperatures. The Seebeck effect will generate a voltage across the two charge-storing junctions, one hot and the other cold, which can then be tapped as a source of electricity. The connection between the two junctions is purely an electrical connection, a wire for example, and this can be designed to have a much lower backflow of heat compared to the prior art of two junctions connected by a thermoelectric material.

Overall, this invention creates an entirely new class of thermoelectric devices that can have much greater efficiency than the prior art and even exceed the efficiency of the best rotating machinery for applications of heating, cooling, and conversion of heat to electricity.

### BRIEF DESCRIPTION OF THE DRAWINGS

FIG. 1 shows one elementary construction of the thermoelectric device of the invention configured for pumping heat, including the provision of non-simultaneous cooling and heating.

FIG. 2 shows the elementary construction of prior art thermoelectric devices configured for pumping heat, including the provision of simultaneous cooling and heating.

FIG. 3 shows two invention thermoelectric devices wherein electrical energy is recycled from one to the other alternately to increase heat pumping efficiency.

FIG. 4a shows the invention thermoelectric device configured for converting heat to electricity. FIG. 4b shows the equivalent electrical circuit of the device of FIG. 4a driving energy into an electrical load.

FIG. 5 shows the prior art thermoelectric device configured for converting heat to electricity.

FIG. 6 shows multiple instances of the invention thermoelectric device connected electrically in series and feasible for thin film deposition or other material stacking means.

FIG. 7 shows multiple instances of the invention thermoelectric device connected electrically in parallel and feasible for thin film deposition or other material stacking means.

FIG. 8 shows the invention thermoelectric device constructed by starting with an electrical double-layer supercapacitor or hybrid supercapacitor (FIG. 8a) and adding a thermoelectric layer to it (FIG. 8b), or equivalently to a battery anode (FIG. 8c).

FIG. 9 shows multiple invention thermoelectric devices acting as heat sink fins that are conveyed as a group into and out of an enclosure alternately, with forced air from fans distributing [cooling or heating] inside and [heating or cooling] outside [respectively]. In FIG. 9a the devices are oriented vertically, and in FIG. 9b they are oriented horizontally and are interleaved when traversing the enclosure wall. FIG. 9 also shows a preferred embodiment of the invention applied to a refrigerator, freezer, room air conditioner, room heater, or oven.

FIG. 10a similarly shows the multiple invention thermoelectric devices of FIG. 9 conveyed into and out of the enclosure, one at a time, through two narrow slits in the wall of the enclosure, one slit acting as an entrance and the other slit acting as an exit. FIG. 10b shows the invention devices arranged in a carousel that rotates them into and out of the enclosure as they transition from hot to cold or cold to hot, with fans recirculating heating or cooling inside and outside the enclosure. The fans of FIG. 10b are pushing air across the devices. FIG. 10c shows the fans pulling air across instead.

FIG. 11 shows invention thermoelectric devices that are not conveyed, but instead are in alternating contact with two fluid flows wherein one fluid flow is part of a fluid loop to a heat exchanger inside the enclosure and the other fluid flow is part of a fluid loop to a heat exchanger outside the enclosure. FIG. 11 also shows a preferred embodiment of the invention applied to a central air conditioner or central heat pump for a house, large room, or building.

FIG. 12 shows a preferred embodiment of the invention applied to cooling of an electronic chip, such as a microprocessor, wherein the invention thermoelectric device is physically in contact with the chip while removing heat and physically in contact with a heat sink while generating heat.

FIG. 13 shows the reduction to practice of the invention with two invention devices, each built from supercapacitor parts as described in FIG. 8b, and both connected together electrically as in FIG. 4a

### DETAILED DESCRIPTION

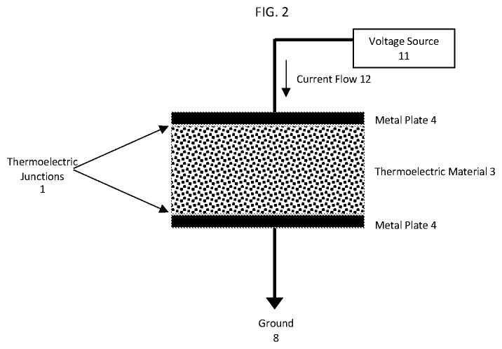

FIG. 2 shows one thermoelectric element of a prior-art thermoelectric device, consisting of a thermoelectric material 3 sandwiched between two metal plates 4, and thereby having two thermoelectric junctions 1. A voltage source 11 provides a continuous current flow 12 through this stack to ground 8.

As the current flows across the metal-to-(n-type) thermoelectric junction 1 top, that junction heats. And, as the same current flows across the thermoelectric-to-metal junction 1 bottom, that junction simultaneously cools. Heating and cooling are both generated simultaneously at either end of the thermoelectric material.

The electrical resistance of the thermoelectric material generates heat and the proximity of the hot junction to the cold junction allows for heat back flow from the hot side to the cold side. These are the two primary loss mechanisms of a prior-art thermoelectric device and are also the primary reasons for thermoelectric devices to have much lower efficiency than vapor-compression cooling systems.

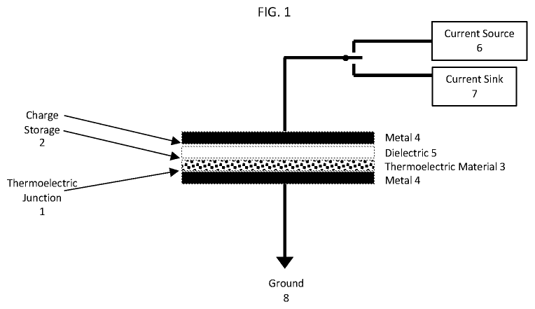

FIG. 1 shows the elemental construction of the invention thermoelectric device. Relative to the prior art stack in FIG. 2, a dielectric 5 layer is added and the thermoelectric material 3 (n-type) layer is much thinner. The insertion of the dielectric 5 layer results a capacitance between the top metal plate 4 and the thermoelectric material 3, and the facing surfaces of each act as capacitor plates. This capacitance allows for charge storage 2 between these two surfaces.

In FIG. 1 a current source 6 feeds charge into the charge storage 2, charging it up. During charging, an electrical current flows across the thermoelectric-to-metal junction 1. This junction will heat while this current flows, similar to the hearting junction of the prior art. However, in FIG. 1, the current does not simultaneously flow through a metal-to-semiconductor junction. Hence, no simultaneous cooling is taking place.

The invention device of FIG. 1 can only heat until the charge storage 2 reaches its maximum limitation, which is typically the electric field breakdown of the dielectric 5. So, this invention device of FIG. 1 accomplishes cooling only for a finite period of time while the device is discharged. During this cooling period (while discharging), the device can be located inside of an enclosure of a refrigerator or inside the wall of a house of building. Or, the device may be inside of a garment worn by a person or animal wanting to be cooled.

Once the cooling (discharging) period ends, this device in FIG. 1 can be moved to the outside of the enclosure, and then re-charged by switching out the current source 6 and switching in the current sink 7. Now, the current is flowing in the opposite direction across the thermoelectric junction 1, and the junction now generates heat. But, this heating is generated outside of the cooled enclosure, or away from the garment-wearing person. By thermally insulating the enclosure or otherwise moving the device to another location, the thermal backflow from this outside heating to the cooled inside can be much lower than the prior art backflow between the thermoelectric junctions 1 in FIG. 2.

Without limitation, the device of FIG. 1 may provide heating in the enclosure or under the garment and cooling outside of the enclosure or away from the garment.

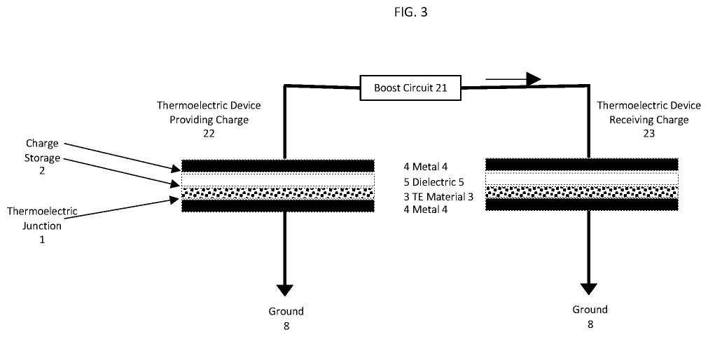

The current sink 7 in FIG. 1 can either flow through a load resistor or be recycled into the power supply of the current source 6 for increased efficiency. Or, two invention thermoelectric devices can be configured such that the discharging of one assists in charging of the other, as illustrated in FIG. 3. The boost circuit 21 boosts the voltage available from the thermoelectric device providing charge 22 up to the voltage needed to charge the second thermoelectric device receiving charge 23 at a desired rate. The desired current, which determines the cooling power of the thermoelectric junction 1 of device 23, is regulated by the boost circuit 21. Once the device 22 is fully discharged and device 23 is fully charged, then the locations of the devices are physically swapped into or out of the enclosure and electrically switched to opposite sides of the boost circuit 21. Boost circuits are also known as DC-DC converters, and are available in many configurations from Digikey and other distributors, with variable voltage capability.

Thermoelectric devices are reversible and, in addition to cooling and heating, can convert heat to electricity. FIG. 5 shows the prior art thermoelectric device in this mode. A heat source Tₕ 32 maintains one thermoelectric junction 1 at a high temperature Tₕ, and a heat sink T_{c} 33 maintains the other thermoelectric junction 1 at a low temperature T_{c}. The thermoelectric (Seebeck) effect generates a voltage 34 relative to ground 8, and this voltage is proportional to the temperature difference Tₕ-T_{c}. Note the same two loss mechanisms are present: heat will backflow from the high temperature side to the low temperature side, and electrical current supplied by the generated voltage 34 will see resistive electrical losses in the thermoelectric material 3. Once again, these losses render a prior art thermoelectric device as uninteresting for most power generation applications.

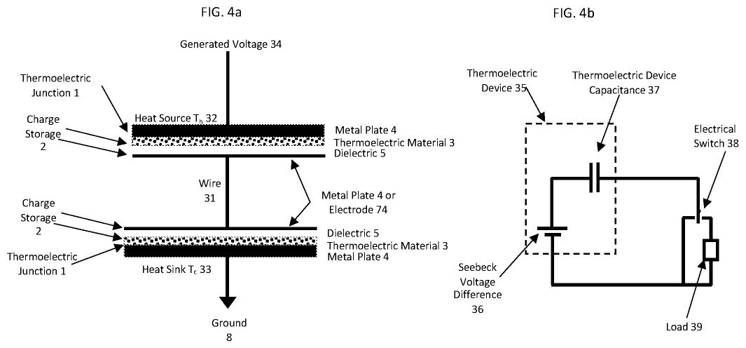

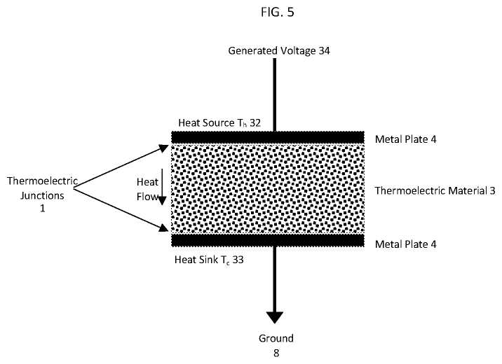

FIG. 4a shows an invention thermoelectric device configured for power generation. The bulk of the thermoelectric material 3 in FIG. 5 has been replaced with a wire 31 connecting to two capacitor metal plates 4, and two dielectric layers 5. When a heat source Tₕ 32 and heat sink T_{c} 33 are applied to thermoelectric junctions 1, a generated voltage 34 relative to ground 8 provides electrical power that charges up the two charge storages 2.

FIG. 4 b contains the invention thermoelectric device 35 of FIG. 4a represented as an equivalent circuit 35 voltage source in series with a capacitor 37. The Seebeck voltage difference 36 is the difference between the contact potentials at the two thermoelectric junctions 1 in FIG. 4a, which are at different temperatures. The thermoelectric device capacitance 37 in FIG. 4b is the equivalent series capacitance of the two series charge storages 2 in FIG. 4a. Electrical switch 38 in FIG. 4b allows for the thermoelectric device 35 to charge up its capacitance 37 in the left position and allows for this capacitance 37 to discharge into the load 39 in the right position. The electrical switch 38 can also be in the open position at times when the load does not need power. Because electrical energy cannot pass direct current DC through a series capacitor in FIG. 4b, the heat source Tₕ 32 and heat sink T_{c} 33 in FIG. 4a must periodically reverse their positions from the [hot and cold] baths, respectively to the [cold and hot baths] respectively of the environment providing the thermal energy. Electrical switch 38 in FIG. 4b is in the left position in the first configuration, and in the right position in the reversed configuration.

The charging of thermoelectric device capacitance 37 in FIG. 4b causes current to flow across the thermoelectric junctions 1 in FIG. 4a, having the effect of cooling the heat source Tₕ 32 and heating the heat sink T_{c} 33, working against these thermal reservoirs. This mechanism is analogous to the “Peltier heat” effect of prior art thermoelectric devices and represents a fundamental thermodynamic limitation of generating electricity from heat.

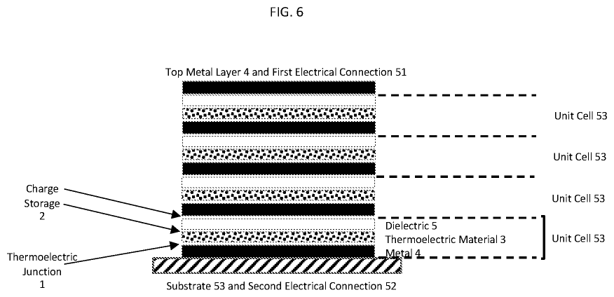

FIG. 6 shows how multiple instances of the invention device in FIG. 1 may be aggregated together and connected electrically in series, but repeating a unit cell 53 and providing a first electrical connection 51 on the top and a second electrical connection 52 on the bottom. As the device in FIG. 6 contains multiple thermoelectric junctions 1, one for each unit cell 53, the cooling power is multiplied by the number of unit cells 53. Hence, the invention may be scaled using the aggregation illustrated in FIG. 6 for applications requiring large amounts of cooling or heating. Note that these series connections in FIG. 6 leads to a high voltage device.

The aggregated device in FIG. 6 also illustrates a means for manufacturing scaled devices using deposition of thin films. Each of the layers in the unit cell may be deposited using well-established thin film deposition techniques such has thermal evaporation, sputtering, chemical vapor deposition (CVD), and many others known to the art. The depositions begin on an electrically conducting substrate 53 layer, which may also serve as the second electrical connection 52.

The aggregated device of FIG. 6 may also represent a scaled-up version of the upper half and the lower half of the power generation device in FIG. 4a. In this case, the generated voltage from the scaled device is multiplied by the number of unit cells in each half.

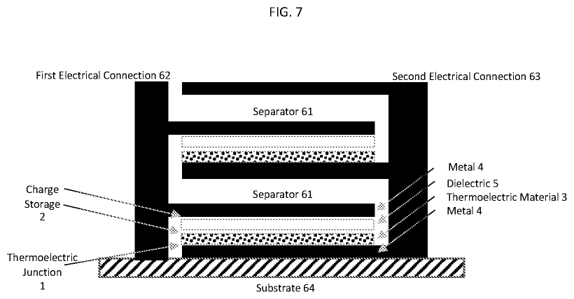

Another way of scaling up the capability of the invention device is to connect multiple unit cells electrically in parallel, as illustrated in FIG. 7, wherein the top electrode metal 4 of each unit cell is connected to a first electrical connection 62 and the bottom electrode metal 4 of each unit cell is connected to a second electrical connection 63. A separator 61 is used to electrically isolate the bottom of one unit cell from the top of another. When configured for either cooling/heating or for power generation, the multiplicity of unit cells scales the capability of the aggregate device. The deposition of the films involves swapping out masks or other targeting means to allow the electrical connections 62 and 63 to be grown stepwise with different materials from the interior films of metal 4, dielectric 5, and thermoelectric material 4. The substrate 64 in FIG. 7 is not electrically conducting and merely provides a structure to hold the film stack. Note that these parallel connections in FIG. 7 leads to a high current device.

The amount of charge that the invention device in FIG. 1, 6, or 7 can store is an important parameter. If the maximum charge storage is low, then a limited amount of cooling takes place before the device must be moved into or out of the enclosure. In some designs based on traditional parallel plate capacitors, the amount of cooling capability is not even enough to overcome the device's thermal mass. In other designs, the device must be moved into and out of the enclosure in microseconds, which is impractical.

One other design approach is to (1) replace the dielectric with an electric double layer as is common in supercapacitors, (2) select a thermoelectric material with a high Seebeck coefficient, such as a material that exhibits the Giant Seebeck effect, and (3) make the thermoelectric material very thin to minimize electrical resistance, as Giant Seebeck materials generally have high electrical resistivities. Note that this design approach is very different from that of the prior art, which involves choosing a material with a maximum thermoelectric material figure of merit Z=S/(ρκ) where material parameters S is the Seebeck coefficient, ρ is the electrical resistivity, and κ is the thermal conductivity.

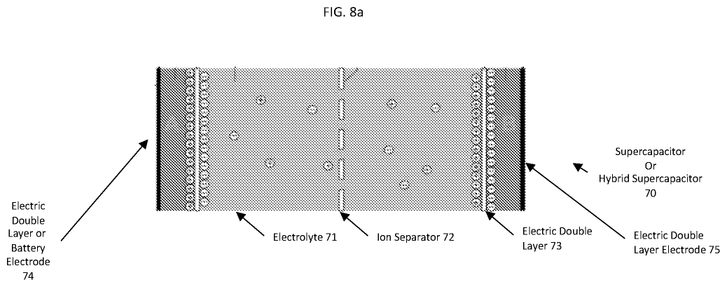

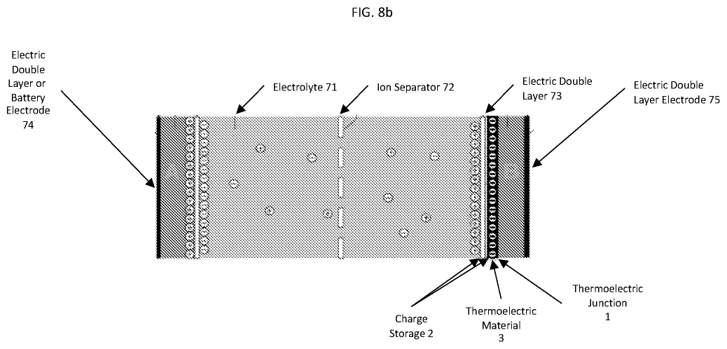

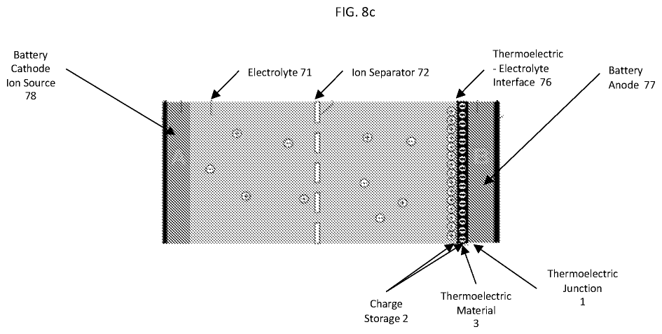

FIG. 8a shows the general construction of a supercapacitor. The electric double layer 73 is a dielectric layer of atomic dimension, and is naturally formed by the solvent containing the electrolyte 71. An electric double layer is formed between ions in an electrolyte 71 and a porous electrode with a large surface area. The atomically narrow gap and large surface area create the supercapacitance effect, increasing charge storage by several orders of magnitude compared to parallel plate capacitors. An ion separator 72 is used to allow ions to flow from one side to the other but prevent an electrical short. A hybrid supercapacitor has a battery electrode 74 replacing one of the two electric double layers 73 such that some of the charge is stored as electrochemical energy and the rest as charged capacitance. The invention device may be built from either an ordinary supercapacitor or from a hybrid supercapacitor.

FIG. 8b illustrates how the invention device may be built from an existing supercapacitor or hybrid supercapacitor. A thermoelectric material 3 is added to the surface of the electric double layer electrode 75. Without limitation, the thermoelectric material 3 could be Carbon 60 or C60, graphene, silicon, germanium, bismuth telluride, lead telluride, Manganese Dioxide, Sumanene, Pentacene, C₁₂BP, BP, C₁₀DNTT, DNTT, C₈BTBT, or C₈PDI or any other thermoelectric material known to the art having a large Seebeck coefficient, and preferably exhibiting the Giant Seebeck effect [1, 2, 6]. The interface between the thermoelectric material 3 and the electrode 75 material forms a thermoelectric junction 1. Charge storage 2 is achieved between the thermoelectric material 3 and the ions in the electrolyte 71.

As the device in FIG. 8b is charged, electrical current flows across thermoelectric junction 1 which causes the device to heat while the device is outside the enclosure. The device continues heating until the accumulated charge storage 2 results in the voltage between electrodes 74 and 75 reaching the rated voltage. At this time, the device would be moved to another location (inside of an enclosure, for example) while being discharged and cooling.

FIG. 8c shows the invention built from a battery by adding the thermoelectric material 3 into the battery's anode 77. In this case, the charge storage 2 is between this thermoelectric material 3 next to ions of opposite polarity in electrolyte, but an electric double layer is not needed. The anode 77 might comprise a traditional battery anode material such as graphite, graphene, silicon, or other material, that is then coated with the thermoelectric material 3. A traditional battery cathode 78 stores the source of the ions and may comprise lithium metal, lithium metal oxide, or other battery cathode material.

The porosity of the electric double layer electrode 75 in FIG. 8b or the battery anode 77 in FIG. 8c is important because the porosity determines the surface area adjacent to the electrolyte 71 which in turn determines the capacity of the capacitor or battery. Hence, it is desirable to maintain the porosity as the thermoelectric material 3 is deposited. Depositing a film on a porous material typically fills in the pores, and compromises the porosity. A method to avoid this loss of porosity is this is to start with an electrode material of a larger pore size such that the deposition of the thermoelectric film reduces the pore size back to the original, desired level.

Depositing the thermoelectric material 3 in FIG. 8b or 8c onto a porous material requires a different process from the more common deposition onto flat substrates. Thermal evaporation of C60, which has a desirably large Seebeck coefficient, has been successful in creating C60 films [1] on flat substrates. The material evaporates from a hot surface like an open-face container and condenses on a cold surface like the flat substrate. Without proper adaptation, this process would merely deposit the C60 on the line-of-sight face of the porous film, and not coat the areas inside the pores. To adapt this process to deposit onto a porous electrode, the electrode could be heated initially to the C60 evaporation temperature, then allow the C60 vapor from the heated container to permeate the pores, and then cool the porous electrode slowly and uniformly so that these vapors condense on the insides of the pores as well as line-of-sight surfaces.

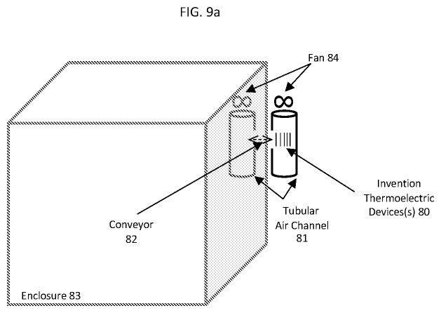

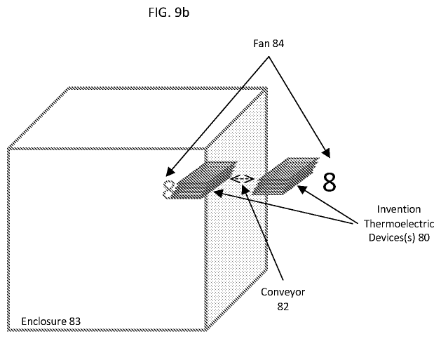

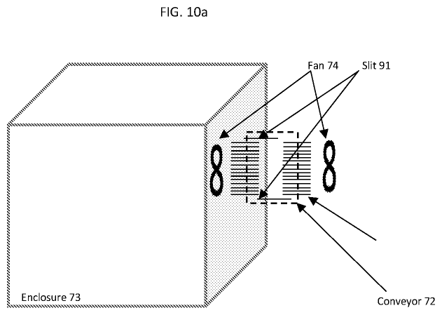

FIG. 9a shows how the Invention Thermoelectric Devices 80 illustrated in FIGS. 1, 3, 6, 7, and 8 may be used to build a room or building air conditioner or heater or refrigerator or freezer or temperature-controlled shipping box, wherein the enclosure is respectively a room, building, refrigerator container, freezer container, or shipping container. Without limitation, these devices may be packaged as flat stacks of material or films in a largely flat package, or the flat stacks may subsequently be wrapped into a cylinder in a largely cylindrical package. An enclosure 83 in FIG. 9a is desired to be at a different temperature set point from its environment outside. For purposes of explanation, it will be assumed that the enclosure is desired to be lower temperature than its environment and that the enclosure has not yet reached its desired temperature. A group of the Invention Thermoelectric Devices 80 are moved inside the enclosure when cooling. When they can no longer cool because they are fully discharged, then they are moved outside the enclosure. In FIG. 9a, the means for moving the group of devices is conveyor 82, which could be a motorized cable or other structure. A fan 84 may be added both inside and outside the enclosure to force air across the devices 80 and rapidly distribute the cooling or heating to a larger area. Tubular air channels 81 may also be added to effectively contain the forced air from the fans 84 to flow mostly across the devices 81. The channel 81 has openings that allows the conveyor 82 to move the devices 81 from/to the inner channel 81 to/from the outer channel 81. Without limitation, the conveyor 82 could swap two sets of devices 80, wherein one set is mostly heating while the other one is mostly cooling.

While FIG. 9a has the devices in a vertical orientation and hence vertical airflow, other embodiments may benefit from horizontal airflow with horizontally oriented devices 80 as illustrated in FIG. 9b. As the inside devices 80 and outside devices 80 swap locations, they may cross over in an interleaved fashion minimize the size of the hole needed in the enclosure.

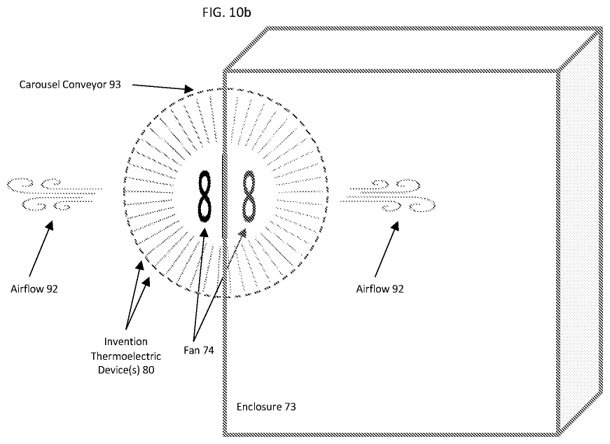

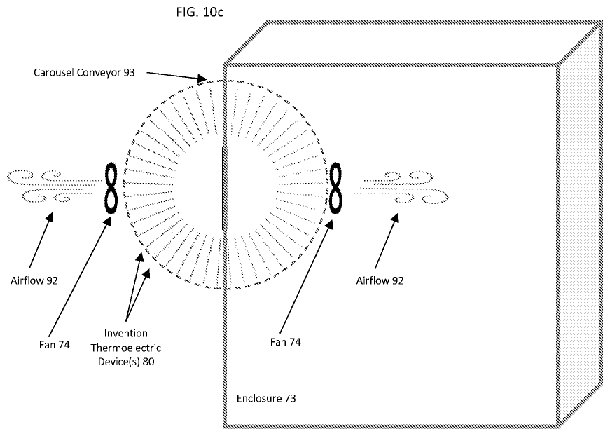

FIG. 10a show another configuration that has smaller openings in the enclosure wall for better thermal insulation. Two narrow Slits 91 represent openings in the enclosure wall, and one Slit 91 allows one Invention Thermoelectric Device 80 to enter the enclosure at a time while the other Slit 91 allows one such device 80 to exit at the same time. The conveyor 72 maintains all of the inside devices 80 in a row and all of the outside devices 80 in a row. These rows of devices largely act as heat sink fins, but are movable piecewise into and out of the enclosure. Fans 74 force air across these rows of devices much like a ductless mini-split air conditioner that employs compressors. Without limitation, the Invention Thermoelectric Devices 80 may be largely flat or cylindrical and move through elongated Slits 91. Also, without limitation, fans 74 in FIG. 10a could be longitudinal fans that move air across a linear array of heated or cooled devices.

FIGS. 10b and 10c show how a rotating carousel conveyor 93 can move arrays of invention devices arranged in a circle inside and outside of the enclosure 73 periodically. Fans 74 in FIG. 10b pull air from above and below the inner diameter of the carousel conveyor 93 and blows it across the invention thermoelectric devices 80 into the interior of the enclosure 73 or to the outside environment. FIG. 10c shows the fans 74 pulling the air along the same paths in FIG. 10b, instead of pushing the air.

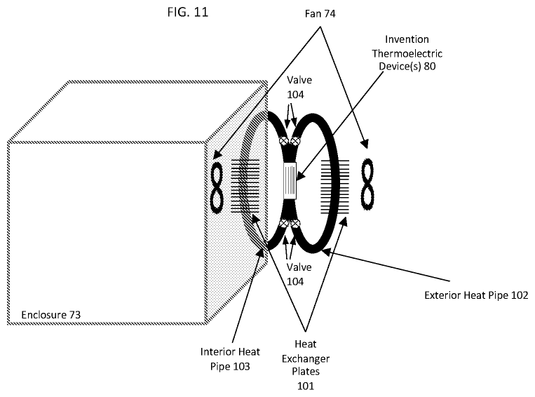

FIG. 11 shows yet another configuration that does not require devices 80 to move at all. Instead, the devices 80, and their attached heat sinks if any, are fixed to or inside of a fluid bath that is thermally connected to an interior heat pipe 103 and an exterior heat pipe 102. When the device 80 is cooling, the fluid in the interior heat pipe 103 is circulating in an interior loop by opening the interior loop valves 104 and closing the exterior loop valves 104. When the device 80 is heating, the fluid in the exterior heat pipe 102 is circulating in an exterior loop by opening exterior loop valves 104 and closing the interior loop valves 104. In FIG. 11, the fluid flow loop is alternated instead of moving the devices into and out of the enclosure. Heat exchanger plates 101 are physically connected to the heat pipes 102 and 103 both inside and outside the enclosure. Fans 74 force air on the heat exchanger plates 101 to distribute cooling inside and heating outside the enclosure. In FIG. 11, two openings are required for the interior heat pipe 103. The illustration in FIG. 11 is a preferred embodiment for central air conditioning, with the invention devices replacing the traditional compressor and evaporator, having both inside and outside heat exchangers.

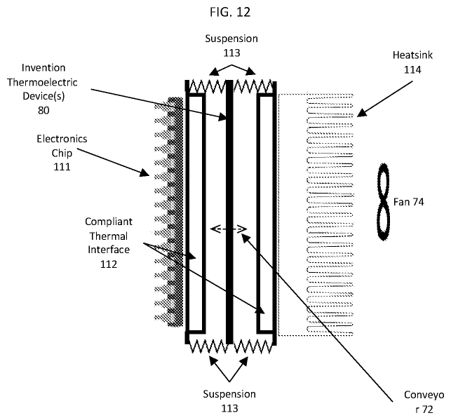

Electronics cooling, especially for microprocessors, is an important function in today's smart devices, computers, and information technology systems. FIG. 12 illustrates how the invention thermoelectric device 80 may be used to cool a microprocessor or other electronics chip 111. A conveyor 72 is used to bring the device 80 into contact with the chip 111 when the device 80 is cooling. The conveyor also moves the device 80 in contact with a heatsink 114 when it is heating. A fan 74 forces air across the fins of heatsink 114 to ultimately dissipate the heat into the environment. It is recognized that the device 80 may not have a perfectly flat and smooth surface, and so a compliant thermal interface 112 may be added that conforms to the device surface under pressure. The compliant thermal interface may be soft extruded graphite, gap filler made of paste or thermally conductive rubber, liquid metal, graphene, or other thermal interface material known to the art. Suspensions 113 provide a means to hold the device in place and compress or expand as needed for the conveyor 72 to move the device back and forth. The suspension could be one or more springs or corrugated rubber or fabric.

One embodiment of FIG. 12 has an air-tight seal between suspension 113, device 80 and the thermal interface 112, creating two air-tight chambers, one on either side of device 80. In this embodiment, the conveyor 72 pumps air into one chamber and out of the other chamber to move the device 80 against one side or the other. This embodiment using air pressure will naturally distribute the force evenly over the device 80 as it is brought against one compliant thermal interface 112 or the other, assisting in good thermal contact.

### Example-Calculation

An example of the invention device as a heat pump used for cooling will be illustrated here, based on the configuration in FIG. 6. A hybrid supercapacitor that is already available on the market is PR3000F02R3-111W254L-T manufactured by Power Responder in Troy NY USA. The construction matches that illustrated in FIG. 6a, and has a Lithium-Ion battery electrode 74 in addition to an electric double layer 73. The form-factor of this supercapacitor is a flat plate with large surface area for exchanging heat as illustrated in FIG. 9-12. This supercapacitor has a capacitance C of 3000 Farads, a mass m of 94 grams, an estimated heat capacity H_{c} of 0.8 joules/gram-degree, a width w of 111 mm and a depth d of 245 mm. The rated voltage V from fully discharged to fully charged is approximately 2 volts. The number of internal capacitor cells n is 7 that are all electrically connected in parallel.

First, we will assume that a thermoelectric material 3 is deposited as a thin film as shown in FIG. 6b, a step added to the manufacturing process of this supercapacitor. The thermoelectric material selected is C60 fullerene, which is a stable form of carbon, readily available in powder form from American Elements in Los Angeles California USA and other suppliers. Furthermore, C60 fullerene exhibits the Giant Seebeck effect according to [1] and [2] with a measured Seebeck coefficient S of 50,000 microvolts per degree at room temperature and an electrical resistivity ρ of 1,000,000 ohm-meters. We will assume that the Seebeck coefficients of all other materials flowing current in the supercapacitor in FIG. 6b are negligible compared to that of the C60 fullerene. The thickness of the deposited C60 film is 10 nanometers, and the film is formed with thermal evaporation as described in [1] and [2] onto each of the 7 internal capacitor elements.

In charging and discharging the invention device, we will use a current I of 5 amps, which is well within the rated current of the supercapacitor. We will also assume a standard air-conditioning application where outside temperature Tₕ is 305 Kelvin (105 Fahrenheit) and the desired inside forced-air temperature T_{c} is 283 Kelvin (55 Fahrenheit). Hence the delta temperature ΔT is 22 Kelvin. Given these conditions the time t required to charge or discharge the device is CV/I or 1200 seconds, or 20 minutes, which is easily offers sufficient time to move devices into and out of enclosures.

The equation for the cooling power is the Peltier cooling minus the heat from electrical resistance minus the power needed to reverse the temperature of the device, or

$${P}_{c} = S {T}_{c} \cdot I - {I}^{2} \{ ρ t / wd ) / n - {H}_{c} m Δ T / t$$

Substituting the values mentioned, the cooling power Pc=70.75−1.31−1.38=68.1 watts. This amount of cooling is easily distributed by forced air over the area of the device with a readily available fan, as the heat transfer is 0.25 watts per square centimeter.

Next, we compute the coefficient of performance, or COP, which is a measure of cooling efficiency and represents the cooling power divided by the electrical input power used to power the device. Assuming that one device while heating discharges into another device while cooling as in FIG. 3 and the boost circuit 21 is 90% efficient, then the electrical input power is the resistive losses plus the voltage times current at the junctions plus 0.1 times the total electrical power. The formula for COP is

$$C O P = {P}_{c} / [ \{ 2 * {I}^{2} \cdot \{ ρ t / wd ) / n + I \cdot S Δ T + ( 0.1 ) * I * V ]$$

Substituting the values mentioned, the COP=68.1/(2.65+5.5+1)=7.44. This efficiency value is much larger than the 1.0 typical for traditional thermoelectric devices and also much higher than the 3.7 for the very best commercial air conditioners based on vapor compression.

Without limitation, it is shown that very high efficiencies and cooling powers may be obtained with other materials than C60. Manganese Dioxide MnO₂ for example has a Seebeck coefficient that has been measured to be 20,000 to 30,000 microvolts per degree [6].

Example-Reduction to Practice

Two built devices will be described here that illustrate this invention: a hybrid supercapacitor with a C60 thermoelectric material that exhibits a Seebeck coefficient that is greater than 10,000 microvolts per degree K, and a symmetric electric double-layer supercapacitor without a C60 thermoelectric material that exhibits a much lower Seebeck coefficient. An available supercapacitor was purchased from Digikey (Minneapolis USA) and its activated carbon-on-aluminum electrodes were removed for use in both of these examples. The manufacturer was Kyocera (Kyoto Japan) and the model number was SCPB20A156SNA.

### Example 1

Supercapacitor with Thermoelectric Material

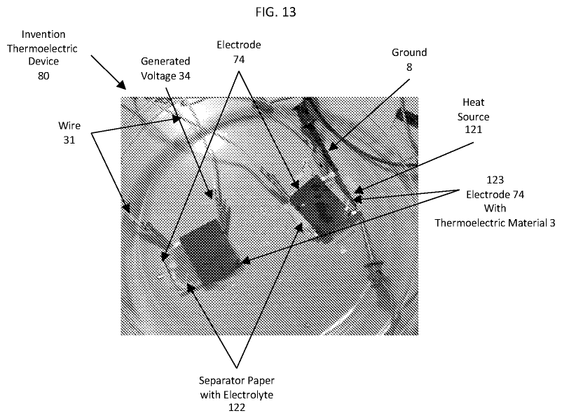

In this example, the construction in FIG. 4a was used to build a thermoelectric generator using the invention, and the apparatus is shown in FIG. 13. Two activated carbon electrodes 74 were removed from a commercial supercapacitor, and then were placed in a vacuum deposition chamber, and 10 nanometers of Carbon 60 fullerene (or C60) was deposited using thermal evaporation, forming the Thermoelectric Material 3 layer in FIG. 4a on electrode 123 in FIG. 13.

These and two other unmodified electrodes from the commercial supercapacitors were arranged as shown in FIG. 4a and FIG. 13, wherein each Metal Plate 4 (FIG. 4a) and Electrode 74 FIG. 13) was a sheet of aluminum foil coated with activated carbon to increase its surface area. Dielectric 5 in FIG. 4b was a piece of separator paper soaked in saltwater 122 in FIG. 13 which, in a supercapacitor, naturally forms a dielectric layer of atomic thickness between the electrolyte and the facing material. In this example illustrated in FIG. 13, two electrolyte-facing electrode materials were C60, and the other two were just activated carbon. The Heat Source Th 32 in FIGS. 4a and 121 in FIG. 13 was a traditional prior-art thermoelectric heater mounted underneath and in contact with the upper supercapacitor in FIG. 4a. A thermocouple was placed on the top of the heated invention device on the right in FIG. 13 to measure its temperature, and the other invention device on the left in FIG. 13 was maintained at room temperature.

With this construction, the Generated Voltage 34 in FIG. 4a and FIG. 13 relative to Ground 8 increased by +20.0 millivolts when the temperature reading of Heat Source Th 32 in FIG. 4a decreased 1.0 degrees C., from 28.3 C to 27.3 C. Hence, the Seebeck coefficient was −20,000 microvolts per degree for this reading. Then, the temperature reading of Heat Source Th 32 was increased 1 degree C. from 28.1 C to 29.1 C, and a voltage decrease of −13 millivolts was seen for Generated Voltage 34. Hence, the Seebeck coefficient was −13,000 microvolts per degree for this reading. Repeats of this experiment recorded a range of Seebeck coefficients between −15,000 and −22,000. All experiments were conducted with the heated supercapacitor at temperatures between 27 C and 32 C.

The literature [1] and [2] indicates that at the temperature of the experiment 28 C or 301 K, a Seebeck coefficient of around 100,000 microvolts per degree would be expected. However, two deficiencies of this experiment are noted, each of which would reduce the measured Seebeck coefficient: (1) the C60 layer was not annealed after deposition reducing its crystallinity, and (2) the C60 would only coat the line-of-sight portions of the surface of the activated carbon but the electrolyte can seep into the deep pores that are not visible from the surface.

Then, the electrodes 123 in FIG. 13 with the C60 thermoelectric layer were replaced with electrodes without this layer. The measured voltage per degree of temperature change was less than 1000 microvolts per degree with the same construction illustrated in FIG. 4a. Such a voltage could be explained by the capacitance change of one supercapacitor that is in series with another, which would result in a voltage change when the charge naturally redistributes. Note that these supercapacitors did have a non-zero residual charge during both experiments.

Clearly, a large Seebeck effect was exhibited and hence a large voltage on a heated supercapacitor when a thermoelectric layer was added, facing the electrolyte, to one of the electrodes, demonstrating the invention of FIG. 4a. Note how the prior art thermoelectric devices would have required a temperature delta across the thermoelectric layer in order to generate such a Seebeck voltage, as in [4,5] or would be absent a thermoelectric layer, as in [3].

In this example, a higher temperature of one whole supercapacitor relative to another whole supercapacitor, connected in series, generated this exceptionally large voltage with the presence of the thermoelectric layer against the dielectric and without a temperature gradient within one capacitor.

### REFERENCES

1. “Giant Seebeck effect in pure fullerene thin films” by Hirotaka Kojima et. al. Applied Physics Express 8, 121301 (2015)
2. “Universality of the giant Seebeck effect in organic small molecules” by Hirotaka Kojima, et. al. Materials Chemistry Frontiers, 2018, 2, 1276
3. “Thermally chargeable supercapacitor working in a homogeneous, changing temperature field”, by Hyuck Lim, Yang Shi, and Yu Qiao, Applied Physics A, 2016, 122:443
4. “Zinc ion thermal charging cell for low-grade heat conversion and energy storage”, by Zhiwei Li, Yinghong Xu, Langyuan Wu, Yufeng An, Yao Sun, Tingting Meng, Hui Dou, Yimin Xuan, and Xiaogang Zhang, Nature Communications, 2022, 13:132
5. “lonic thermoelectric supercapacitors”, by D. Zhao, H. Wang, Z. U. Khan, J. C. Chen, R. Gabrielsson, M. P. Jonsson, M. Berggren, and X. Crispin, Energy and Environmental Science Issue 4,2016
6. “Giant Seebeck coefficient thermoelectric device of MnO₂ powder” by FangFang Song, LimingWu and S Liang, Nanotechnology 23 (2012)

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. A thermoelectric device, the thermoelectric device comprising:
(a) a top electrode;
(b) a bottom electrode;
(c) a dielectric layer; and
(d) a thermoelectric layer;
(e) where the dielectric layer is sandwiched between the top electrode and the thermoelectric layer,
(f) where the thermoelectric layer is sandwiched between the dielectric layer and the bottom electrode,
(g) where a thermoelectric junction forms between the thermoelectric layer and the bottom electrode.

21. The thermoelectric device described in claim 21,
(a) wherein the thermoelectric layer is n type material;
(b) where the thermoelectric layer heats up when the current flows across the thermoelectric junction,
(c) where the thermoelectric layer cools down when the current flows in reverse across the thermoelectric junction.

21. The thermoelectric device described in claim 21,
(a) wherein the thermoelectric layer is p type material;
(b) where the thermoelectric layer cools down when the current flows across the thermoelectric junction,
(c) where the thermoelectric layer heats up when the current flows in reverse across the thermoelectric junction.

21. The thermoelectric device described in claim 21,
(a) wherein the dielectric layer is comprised of a double electric layer;
(b) where the double electric layer enhances the capacitance characteristics of thermoelectric device.

24. The thermoelectric device described in claim 24, (a) wherein the top electrode comprises a surface;
(b) wherein the thermoelectric layer comprises a surface;
(c) wherein the double electric layer comprises electrolyte;
(d) where the surface of the top electrode facing the electrolyte is porous and has a large surface area;
(e) where the surface of the thermoelectric layer facing the electrolyte is porous and has a large surface area.

21. The thermoelectric device described in claim 21,
(a) where the top electrode is doped with ions; or
(b) where the bottom electrode is doped with ions.

26. The thermoelectric device described in claim 26,
(a) where the ions are Lithium ions.

21. The thermoelectric device described in claim 21,
(a) wherein the thermoelectric layer is comprised of a material with a Seebeck coefficient greater than 1000 microvolts per degree Kelvin.

28. The thermoelectric device described in claim 28,
(a) where the material with a Seebeck coefficient greater than 1000 microvolts per degree Kelvin is one of Carbon 60 fullerene C₆₀, Sumanene, Pentacene, C₁₂BP, BP, C₁₀DNTT, DNTT, C₈BTBT, MnO₂, and C₈PDI.

30. A heat distribution system, the heat distribution system comprising,
(a) or more thermoelectric devices, as described in claim 21;
(b) an insulated enclosure;
(c) where the insulated enclosure is configured so the one or more thermoelectric devices can be taken in and out of the insulated enclosure.

31. The heat distribution system described in claim 30, further comprising:
(a) a working fluid; and
(b) a means to move the working fluid to distribute heating and cooling inside or outside the insulated enclosure.

32. The heat distribution system described in claim 31,
(a) where the working fluid is air, and
(b) where the means to move the working fluid is a fan.

33. The heat distribution system described in claim 31,
(a) where the working fluid is a liquid, and
(b) where the means to move the working fluid is pump, valves and pipes.

34. The heat distribution system described in claim 33, further comprising:
(a) a heat exchanger;
(b) where the heat exchanger is physically connected to the pipes both inside and outside of the insulated enclosure.

35. The heat distribution system described in claim 30, further comprising
(a) a means to move the one or more thermoelectric devices into or out of the insulated enclosure.

36. The heat distribution system described in claim 35,
(a) where the means to move the one or more thermoelectric devices is a rotary or a linear conveyor.

37. A thermoelectric system, the thermoelectric system comprising:
(a) a first and a second thermoelectric devices, the first and the second thermoelectric devices as described in claim 21;
(b) where a stored electrical energy from one of the first and the second thermoelectric devices is recycled into the other of the first and the second thermoelectric device to reduce the input power required to maintain cooling or heating. 38 A thermoelectric system, the thermoelectric system comprising:
(a) a first and a second thermoelectric device, the first and the second thermoelectric devices as described in claim 21;
(b) a boost circuit; the boost circuit comprising:
(i) an input;
(ii) an output;
(c) where the input of the boost circuit is electrically connected to the first thermoelectric device and the output of the boost circuit is electrically connected to the second thermoelectric device,
(d) where the boost circuit boosts the voltage available from the first thermoelectric device to activate the second thermoelectric device.

39. A power generation system, the power generation system comprising,
(a) two or more thermoelectric devices, the two or more thermoelectric devices as described in claim 21;
(b) where the two or more thermoelectric devices are connected in series,
(c) where some of the thermoelectric devices are maintained a given temperature and the rest of the two or more thermoelectric devices are maintained at a different temperature,
(d) where a voltage is generated by the two or more thermoelectric device connected in series due to the different temperatures.

40. The power generation system described in claim 39, the power generation system further comprising,
(a) a switch;
(b) where the switch is connected to the two or more thermoelectric devices,
(c) where the switch in a first position allows a discharge of electrical energy from the two or more thermoelectric devices to a load,
(d) where the switch in a second position allows a charge of electrical energy to the two or more thermoelectric devices.
